(19) United States
(12) Patent Application Publication
(10) Pub. No.: US 2009/0267805 A1
(43) Pub. Date: Oct. 29, 2009

(54) CONTROL APPARATUS AND ELECTRONIC DEVICE USING THE SAME

(75) Inventors: LEI JIN, Shenzhen City (CN); KIM-YEUNG SIP, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/428,481

(22) Filed: Apr. 23, 2009

(30) Foreign Application Priority Data
Apr. 24, 2008 (CN) 200810301272.X

(51) Int. Cl. H03K 17/94

(52) U.S. Cl. 341/20

(57) ABSTRACT

A control apparatus includes a motion sensor, an image acquisition device, a processor and a holding device. The motion sensor senses head movements of an operator and generates sensing signals. The image acquisition device captures images of the eye of the operator. The processor calculates a displacement of the motion sensor according to the sensing signals from the motion sensor, converts the displacement into displacement signals, analyzes the images to determine eyelid movements of the operator, and generates activation commands according to the eyelid movements. The holding device secures the motion sensor and the processor to the head of the operator and positions the image acquisition device in front of the eye of the operator.

### BACKGROUND

1. Technical Field

Embodiments of the present disclosure relate to control apparatus, and more particularly to a control apparatus operable by eye and head movements and an electronic device using the control apparatus.

2. Description of Related Art

Electronic devices, such as computers and electronic gaming machines, each of which commonly includes a control apparatus, such as a mouse or a game handle, for controlling the electronic device, which often requires the use of both hands. However for a handicapped person or someone who may want to use his hands for other tasks when using a computer or playing an electronic video game, a mouse and a keyboard can be a hindrance.

What is needed, therefore, is a hands free control apparatus.

### BRIEF DESCRIPTION OF THE DRAWINGS

FIG. 1 is a schematic diagram of one embodiment of an electronic device with a control apparatus thereof being attached to the head of an operator.

FIG. 2 is a schematic diagram of one embodiment of a holding device of the control apparatus for securing the control apparatus to the head of the operator.

FIG. 3 is a schematic diagram of another embodiment of a holding device of the control apparatus for securing the control apparatus to the head of the operator.

### DETAILED DESCRIPTION

All of the processes described hereinafter may be embodied in, and fully automated via, functional code modules executed by one or more general purpose computers or processors. The code modules may be stored in any type of computer-readable mediums or other storage devices.

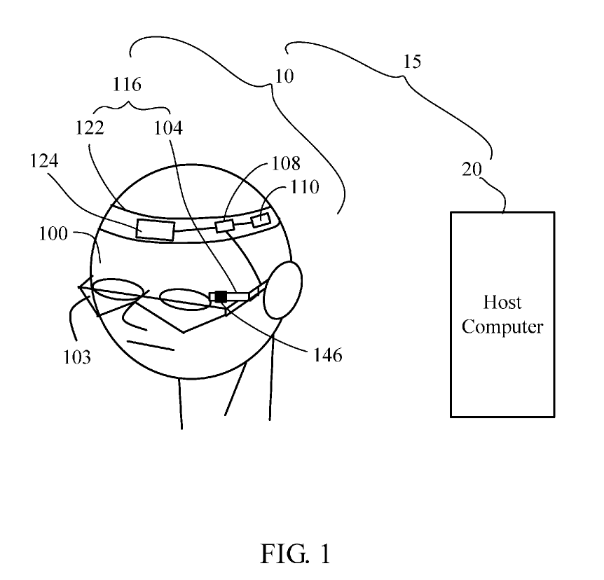

FIG. 1 is a schematic diagram of one embodiment of an electronic device 15 with a control apparatus 10 thereof being attached to the head of the operator 100. The electronic device 15 includes the control apparatus 10 and a host computer 20. The control apparatus 10 connects with the host computer 20 for controlling the host computer 20 to perform movement and activation operations. In this embodiment, the control apparatus 10 acts as a mouse of a computer that directs a cursor to select and manipulate text or graphics. In another embodiment, the control apparatus 10 acts as a game handle that controls a game machine to move and manipulate game objects.

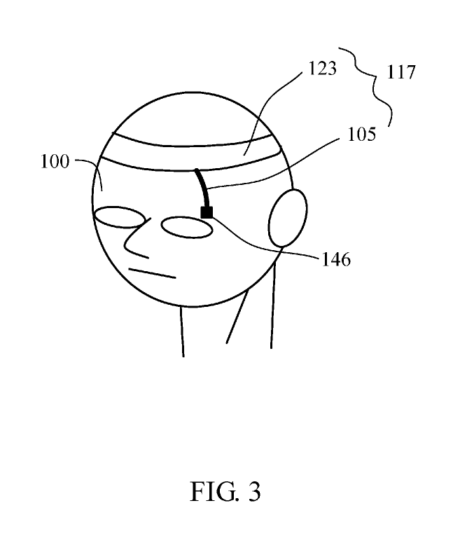

The control apparatus 10 includes a motion sensor 124, an image acquisition device 146 (shown in FIG. 3), a processor 108, an output unit 110 and a holding device 116. The motion sensor 124 and the image acquisition device 146 are connected to the processor 108. The processor 108 is connected to the output unit 110. The output unit 110 has a wireless or wired connection with the host computer 20. In this embodiment, the output unit 110 wirelessly communicates with the host computer 20.

The holding device 116 secures the motion sensor 124, the processor 108, and the output unit 110 to the head of the operator 100 and positions the image acquisition device 146 in front of the eye of the operator 100.

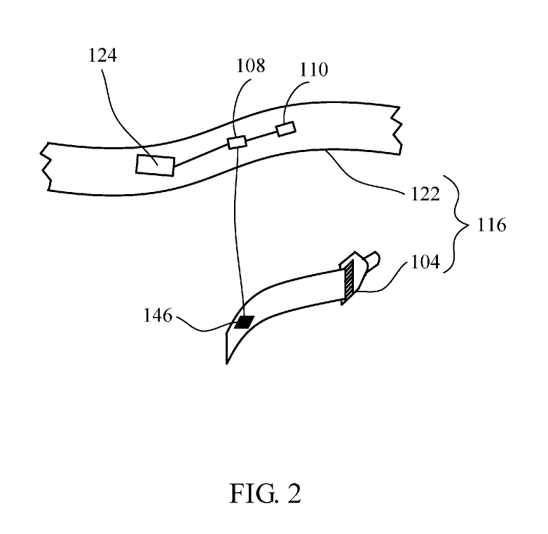

Referring to FIG. 2, in this embodiment, the holding device 116 includes two separate members, e.g. a first member 122 and a second member 104. The first member 122 can be a flexible printed circuit board that is secured to the head of the operator 100. The motion sensor 124, the processor 108 and the output unit 110 are mounted on the flexible printed circuit board and are electrically connected to each other on the flexible printed circuit board. The second member 104 can be a buckle that can be attached to eyeglasses 103 worn by the operator 1 00. The image acquisition device 146 is mounted on a side of the second member 104.

Referring to FIG. 3, in another embodiment, the holding device 117 is integrated in a single piece. The holding device 117 includes a first member 123 and a second member 105. The first member 123 can be a flexible printed circuit board that is secured to the head of the operator 100. The motion sensor 124, the processor 108 and the output unit 110 are mounted on the flexible printed circuit board 123 and are electrically connected to each other on the flexible printed circuit board. The second member 105 can be an arm that is fixed to the first member 123 and extends to front of the eye of the operator 100. The image acquisition device 146 is fixed at a free terminal of the second member 105 and is positioned in front of the eye of the operator 100.

The motion sensor 124 is used for sensing movements of the head of the operator 100, generating sensing signals in response and sending the sensing signals to the processor 108.

In this embodiment, the motion sensor 124 can be a dual axis piezoresistive accelerometer. The dual axis piezoresistive accelerometer 124 senses head movements of the operator 100, generates corresponding voltages according to the head movements and sends the voltages to the processor 108.

The image acquisition device 146 captures images of the eye of the operator 100 at regular intervals and sends the images to the processor 108. The image acquisition device 146 can be, for example, a pickup camera or a universal serial bus (USB) webcam.

The processor 108 enables the motion sensor 124, calculates displacement of the head of the operator 100 according to the sensing signals from the motion sensor 124, converts the displacement into displacement signals and sends the displacement signals to the host computer 20 via the output unit 110. The processor 108 further calculates the horizontal and vertical displacement according to the voltages from the motion sensor 124 and converts the horizontal and vertical displacement into horizontal and vertical displacement signals.

The processor 108 further enables the image acquisition device 146 to capture images of the eye of the operator 100, analyzes the images to determine eyelid movements of the operator 100, generates activation commands according to the eyelid movements and sends the activation commands to the host computer 20 via the output unit 110. It can be understood that various image processing methods, such as image segmentation methods, can be used to analyze the images. In this embodiment, the processor 108 converts the images into gray images, extracts eye features of each of the gray images and determines a eyelid movement of the operator 100 according to at least one of the eye features of the gray images. For example, the eye features can be one or more selected from a group comprising a position of the eyelid, an iris and a white part of the eye. As an illustration, the processor 108 calculates a width of an eyelid slit between an upper margin and a lower margin of the eyelid and determines the eyelid movement based on a change of the width of the eyelid slit.

The processor 108 further calculates a number of the eyelid movements within a scheduled time span and generates the activation commands according to the number of the eyelid movements within the scheduled time span. As an illustration, if the operator 100 blinks three times within a second, it means that the operator 100 wants to click a left button of the mouse. Accordingly, the processor 108 generates a left-button command and sends the left-button command to the host computer 20 via the output unit 110.

The output unit 110 sends the displacement signals and the activation command to the host computer 20. The output unit 110 can be a BLUETOOTH transmission circuit or a universal serial bus (USB) transmission circuit. Accordingly, when using a wired USB connection, the control apparatus 10 can be provided power by the host computer 20. The control apparatus 10 can be powered by a battery pack mounted on the holding device 116 when the output unit 110 uses BLUETOOTH.

The host computer 20 receives the displacement signals and the activation commands and performs corresponding operations. In this embodiment, if the control apparatus 10 acts as the mouse of the computer, the host computer 20 directs the cursor to select and manipulate text or graphics on a display screen. In another embodiment, if the control apparatus 10 acts as the game handle, the host computer 20 moves and manipulates game objects.

Although certain inventive embodiments of the present disclosure have been specifically described, the present disclosure is not to be construed as being limited thereto. Various changes or modifications can be made to the present disclosure without departing from the scope and spirit of the present disclosure.

What is claimed is:

1. A control apparatus comprising:
a motion sensor sensing head movements of an operator and generating sensing signals;
an image acquisition device capturing images of the eye of the operator;
a processor calculating a displacement of the motion sensor according to the sensing signals from the motion sensor, converting the displacement into displacement signals, and analyzing the images to determine eyelid movements of the operator, generating activation commands according to the eyelid movements; and
a holding device securing the motion sensor and the processor to the head of the operator, and positioning the image acquisition device in front of the eye of the operator.

2. The control apparatus of claim 1, wherein the holding device comprises a first member and a second member separated from the first member, the first member is a flexible printed circuit board that is secured to the head of the operator, and the second member is a buckle that is attached to eyeglasses worn by the operator.

3. The control apparatus of claim 1, wherein the holding device is integrated in a single piece and comprises a first member and a second member, the first member is a flexible printed circuit board that is secured to the head of the operator, and the second member is an arm that is fixed to the first member and extends in the front of the eye of the operator.

4. The control apparatus of claim 1, wherein the processor further calculates a number of the eyelid movements within a scheduled time span and generates the activation commands according to the number of the eyelid movements within the scheduled time span.

5. The control apparatus of claim 1, wherein the processor further extracts eye features from each of the images and determines the eyelid movements according to at least one of the eye features.

6. The control apparatus of claim 5, wherein the eye features comprise a position of the eyelid, the iris and the white part of the eye.

7. A control apparatus comprising:
a motion sensor attached to the head of an operator, for sensing head movements of the operator and generating sensing signals;
an image acquisition device attached to the head of the operator and in front of the eye of the operator, for capturing images of the eye of the operator; and
a processor for calculating a displacement of the motion sensor according to the sensing signals from the motion sensor, converting the displacement into displacement signals, analyzing the images to determine eyelid movements of the operator and generating activation commands according to the eyelid movements.

8. The control apparatus of claim 7, further comprising a holding device, wherein the holding device secures the motion sensor and the processor to the head of the operator and positions the image acquisition device in front of the eye of the operator.

9. The control apparatus of claim 8, wherein the holding device comprises a first member and a second member separated from the first member, the first member is a flexible printed circuit board that is secured to the head of the operator, and the second member is a buckle that is attached to eyeglasses worn by the operator.

10. The control apparatus of claim 8, wherein the holding device is integrated in a single piece and comprises a first member and a second member, the first member is a flexible printed circuit board that is secured to the head of the operator, and the second member is an arm that is fixed to the first member and extends to the front of the eye of the operator.

11. The control apparatus of claim 7, wherein the processor further calculates a number of the eyelid movements within a scheduled time span and generates the activation commands according to the number of the eyelid movements within the scheduled time span.

12. The control apparatus of claim 7, wherein the processor further extracts eye features from each of the images and determines the eyelid movements according to at least one of the eye features.

13. The control apparatus of claim 12, wherein the eye features comprise a position of the eyelid, the iris and the white part of the eye.

14. An electronic device comprising a host computer and a control apparatus, the control apparatus comprising:
a motion sensor sensing head movements of an operator and generating sensing signals;
an image acquisition device capturing images of the eye of the operator;
a processor calculating a displacement of the motion sensor according to the sensing signals from the motion sensor, converting the displacement into displacement signals, analyzing the images to determine eyelid movements of the operator and generating activation commands according to the eyelid movements; and
a holding device securing the motion sensor and the processor to the head of the operator and positioning the image acquisition device in front of the eye of the operator.

15. The control apparatus of claim 14, wherein the holding device comprises a first member and a second member separated from the first member, the first member is a flexible printed circuit board that is secured to the head of the operator, and the second member is a buckle that is attached to eyeglasses worn by the operator.

16. The control apparatus of claim 14, wherein the holding device is integrated in a single piece and comprises a first member and a second member, the first member is a flexible printed circuit board that is secured to the head of the operator, and the second member is an arm that is fixed to the first member and extends to the front of the eye of the operator.

17. The electronic device of claim 14, wherein the processor further calculates a number of the eyelid movements within a scheduled time span and generates the activation commands according to the number of the eyelid movements within a scheduled time span.

18. The electronic device of claim 14, wherein the processor further extracts eye features from each of the images and determines the eyelid movements according to at least one of the eye features.

19. The electronic device of claim 18, wherein the eye features comprise a position of the eyelid, the iris and the white part of the eye.
